(19) United States
(12) Patent Application Publication
(10) Pub. No.: US 2025/0273570 A1
(43) Pub. Date: Aug. 28, 2025

(54) WIRING STRUCTURE WITH CONDUCTIVE FEATURES HAVING DIFFERENT CRITICAL DIMENSIONS, AND METHOD OF MANUFACTURING THE SAME

(71) Applicant: NANYA TECHNOLOGY CORPORATION, NEW TAIPEI CITY (TW)

(72) Inventor: MIN-CHUNG CHENG, TAOYUAN CITY (TW)

(21) Appl. No.: 19/204,932

(22) Filed: May 12, 2025

Related U.S. Application Data
(63) Continuation of application No. 17/879,995, filed on Aug. 3, 2022.

(51) Int. Cl. H01L 23/528; H01L 21/768; H01L 23/522

(52) U.S. Cl. CPC H01L 23/5283; H01L 21/76816; H01L 21/76831; H01L 21/76843; H01L 21/76877; H01L 23/5226

(57) ABSTRACT

The present application provides a wiring structure, a semiconductor device having the wiring structure, and a method of manufacturing the semiconductor device. The wiring structure includes a substrate, a metallic layer above the substrate, at least one first conductive feature and at least one second conductive feature. The first and second conductive features are disposed between the substrate and the metallic layer; the first conductive feature has a first critical dimension, and the second conductive feature has a second critical dimension less than the first critical dimension. An effective resistance of the wiring structure can be adjusted by changing the critical dimensions of the first and second conductive features. The semiconductor device including the wiring structure and a method of manufacturing the semiconductor device are also provided.

### CROSS-REFERENCE TO RELATED APPLICATION

This application is a continuation application of U.S. Non-Provisional application Ser. No. 17/879,995 filed Aug. 3, 2022, which is incorporated herein by reference in its entirety.

### TECHNICAL FIELD

The present disclosure relates to a wiring structure for use in a semiconductor integrated circuit and a method of manufacturing the same, and more particularly, to a metallic interconnection with conductive features having different critical dimension and a method of manufacturing the same.

### DISCUSSION OF THE BACKGROUND

Manufacture of a semiconductor device is normally divided into two major phases. “Front end of line” (FEOL) is dedicated to creation of all active components, such as transistors in or on a single substrate of the semiconductor device, and “back end of line” (BEOL) creates metal wirings which connect the transistors to each other and provide power to the semiconductor device. The FEOL consists of a repeated sequence of steps that modify electrical properties of part of a wafer surface and build new material above selected regions. Once all active components are created, a second phase of manufacturing (i.e., the BEOL) begins. During the BEOL, metal wires and metal interconnections (“vias”) are created to establish connection of the semiconductor device, wherein the metal interconnections are used to electrically connect lower and upper metal wires.

This Discussion of the Background section is provided for background information only. The statements in this Discussion of the Background are not an admission that the subject matter disclosed in this Discussion of the Background section constitute prior art to the present disclosure, and no part of this Discussion of the Background section may be used as an admission that any part of this application, including this Discussion of the Background section, constitutes prior art to the present disclosure.

### SUMMARY

One aspect of the present disclosure provides a wiring structure. The wiring structure includes a semiconductor element, a metallic layer, at least one first conductive feature, at least one second conductive feature, and at least one insulative liner. The metallic layer is above the semiconductor element. The first conductive feature is disposed between the semiconductor element and the metallic layer and has a first critical dimension. The second conductive feature, between the semiconductor element and the metallic layer, has a second critical dimension less than the first critical dimension. The insulative liner encloses the second conductive feature.

In some embodiments, a sum of the second critical dimension and two times a thickness of the insulative liner is equal to the first critical dimension.

In some embodiments, the wiring structure further comprises a dielectric layer enclosing the first conductive feature and the insulative liner.

In some embodiments, the first conductive feature and the second conductive feature contact the semiconductor element and the metallic layer, respectively.

In some embodiments, a topmost layer of the semiconductor element where the first and second conductive features are connected is made of conductive material.

In some embodiments, the first and second conductive features are surrounded by diffusion barrier liners.

One aspect of the present disclosure provides a semiconductor device. The semiconductor device includes a substrate, a wiring structure disposed over the substrate, and an interconnection structure between the substrate and the wiring structure for connecting the wiring structure to the substrate. The wiring structure includes a first metallic layer, a second metallic layer, at least one first conductive feature, at least one second conductive feature, and at least one isolation liner. The second metallic layer is disposed above the first metallic layer, and the first and second conductive features are disposed between the first and second metallic layers. The first conductive feature has a first critical dimension, and the second conductive feature has a second critical dimension less than the first critical dimension. The isolation liner encloses the second conductive feature.

In some embodiments, a sum of the second critical dimension and two times a thickness of the insulative liner is equal to the first critical dimension.

In some embodiments, the wiring structure further comprises an inter-layer dielectric (ILD) layer enclosing the first conductive feature and the insulative liner.

In some embodiments, the first conductive feature and the second conductive feature contact the first and second metallic layers, respectively.

In some embodiments, the interconnection structure includes an insulating layer, at least one first conductive block and at least one second conductive block, wherein the insulating layer is disposed on the substrate. The first conductive block, penetrating through the insulating layer, has a third critical dimension, and the second conductive block, penetrating through the insulating layer, has a fourth critical dimension less than the third critical dimension.

In some embodiments, the semiconductor device includes at least one insulative liner interposed between the insulating layer and the second conductive block.

In some embodiments, a sum of the fourth critical dimension and two times a thickness of the insulative liner is equal to the third critical dimension.

In some embodiments, the first and second conductive blocks contact the first metallic layer.

In some embodiments, the first and second conductive features are surrounded by diffusion barrier liners.

In some embodiments, the wiring structure is formed over the substrate during back-end-of-line processes.

One aspect of the present disclosure provides a method of manufacturing a semiconductor device. The method includes steps of depositing a dielectric layer on a substrate, creating a plurality of openings penetrating through the dielectric layer, forming at least one insulative liner in at least one of the openings, and depositing a first conductive material in the openings to form at least one first conductive block physically connected to the dielectric layer and at least one second conductive block surrounded by the insulative liner.

In some embodiments, the formation of the insulative liner includes steps of forming at least one first sacrificial block in at least one of the openings, depositing an insulative film on the first sacrificial block and the dielectric layer and in the openings, and removing horizontal portions of the insulative film.

In some embodiments, the formation of the first sacrificial block includes steps of depositing a first sacrificial layer on the dielectric layer and in the openings, performing an exposure process to expose portions of the first sacrificial layer, and performing a developing process to remove the exposed portion of the first sacrificial layer.

In some embodiments, the method further includes a step of depositing a diffusion barrier layer in the openings prior to the deposition of the first conductive material.

In some embodiments, the method further includes steps of depositing a first metallic layer to cover the dielectric layer, the first conductive block and the second conductive block, depositing an inter-layer dielectric (ILD) layer on the first metallic layer, creating a plurality of trenches penetrating through the ILD layer, forming at least one isolation liner in at least one of the trenches, depositing a second conductive material in the trenches to form at least one first conductive feature surrounded by the ILD layer and at least one second conductive feature surrounded by the isolation liner, and depositing a second metallic layer to cover the ILD layer, the first conductive feature and the second conductive feature.

With the above-mentioned configurations of the wiring structure, including the conductive features having different critical dimensions, the effective resistance of the wiring structure formed during the back-line-of-line processes can be effectively controlled.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1 is a cross-sectional view of a semiconductor device in accordance with some embodiments of the present disclosure.

FIG. 2 is a flow diagram illustrating a method of manufacturing a semiconductor device in accordance with some embodiments of the present disclosure.

FIGS. 3 through 24 illustrate cross-sectional views of intermediate stages in the formation of a semiconductor device in accordance with some embodiment of the present disclosure.

### DETAILED DESCRIPTION

Embodiments, or examples, of the disclosure illustrated in the drawings are described below using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

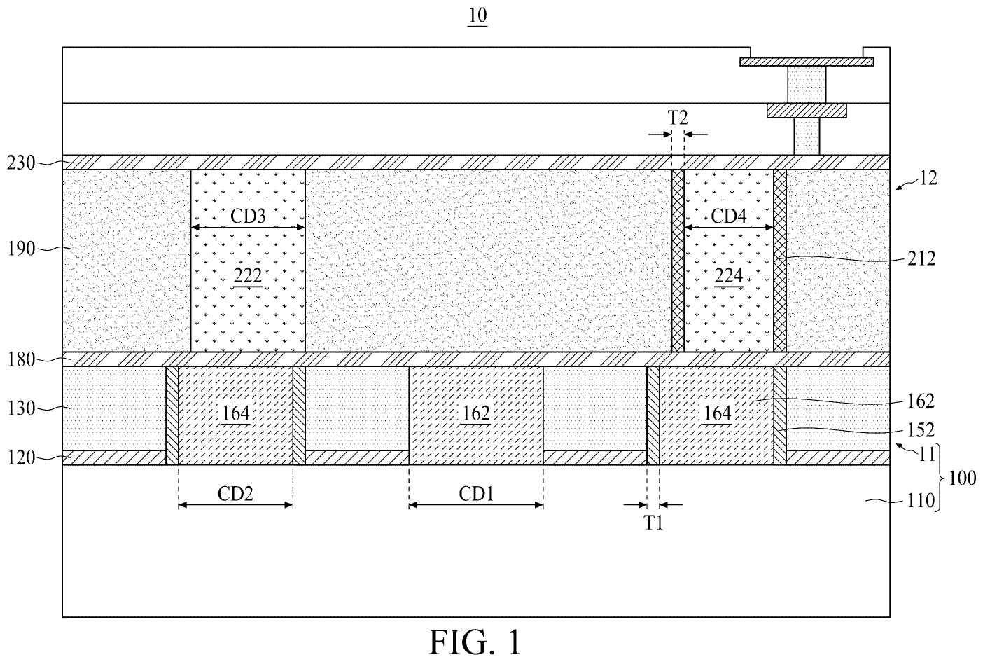

FIG. 1 is a cross-sectional view of a semiconductor device 10 in accordance with some embodiments of the present disclosure. Referring to FIG. 1, the semiconductor device 10 includes a wiring structure 12 and a semiconductor element 100 including a substrate 110 and an interconnection structure 11; the interconnection structure 11 is sandwiched between the substrate 110 and the wiring structure 12 for connecting the wiring structure 12 to the semiconductor device 10. The substrate 110 may have one or more main components (not shown) during front-end-of-line processes.

The interconnection structure 11, disposed on the substrate 110, includes one or more insulative liners 152, one or more first conductive blocks 162, and one or more second conductive blocks 164 surrounded by the insulative liners 152. The first conductive block 162 has a first critical dimension CD1, and the second conductive block 164 has a second critical dimension CD2 less than the first critical dimension CD1. The interconnection structure 11 further includes a block layer 120 and a dielectric layer 130 enclosing the first conductive block 162 and the insulative liners 152. As shown in FIG. 1, the block layer 120, including silicon-containing material, is interposed between the substrate 110 and the dielectric layer 130. The block layer 120 may have a thickness less than a thickness of the dielectric layer 130.

The wiring structure 12 includes a first metallic layer 180 covering the interconnection structure 11, a second metallic layer 230 above the first metallic layer 180, an isolation liner 212, a first conductive feature 222 and a second conductive feature 224 between the first and second metallic layers 180 and 230. The wiring structure 12 may further include an inter-layer dielectric (ILD) layer 190 disposed between the first and second metallic layers 180 and 230 and enclosing the first conductive feature 222 and the second conductive feature 224, wherein the second conductive feature 224 is surrounded by the isolation liner 212. The first conductive feature 222 penetrates through the ILD layer 190, is connected to the first and second metallic layers 180 and 230, and has a third critical dimension CD3. The second conductive feature 224 is physically connected to the first and second metallic layers 180 and 230, and has a fourth critical dimension CD4 less than the third critical dimension CD3.

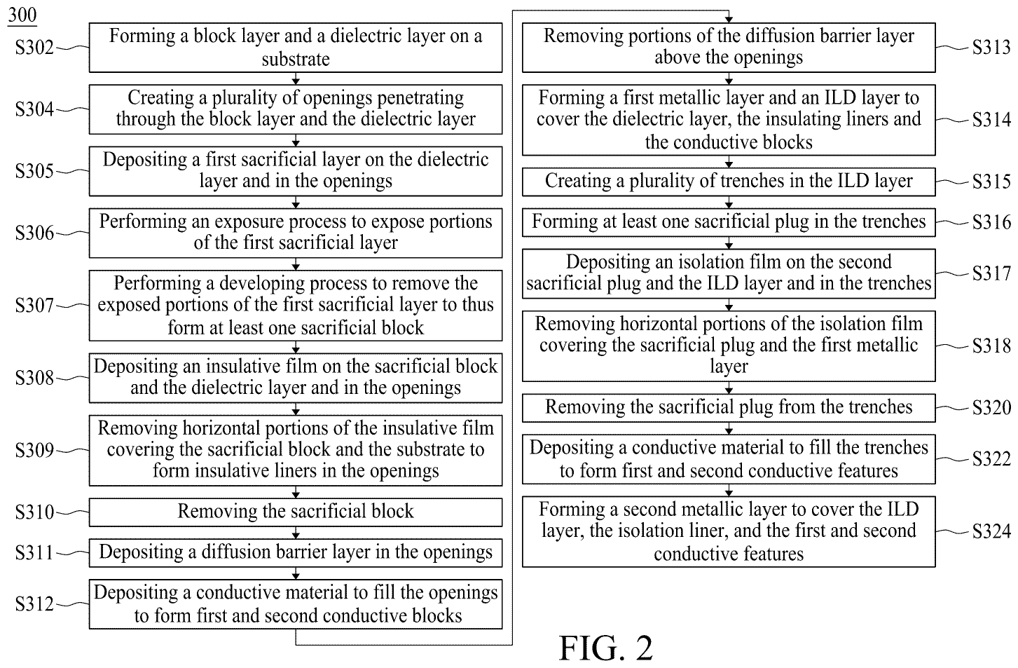

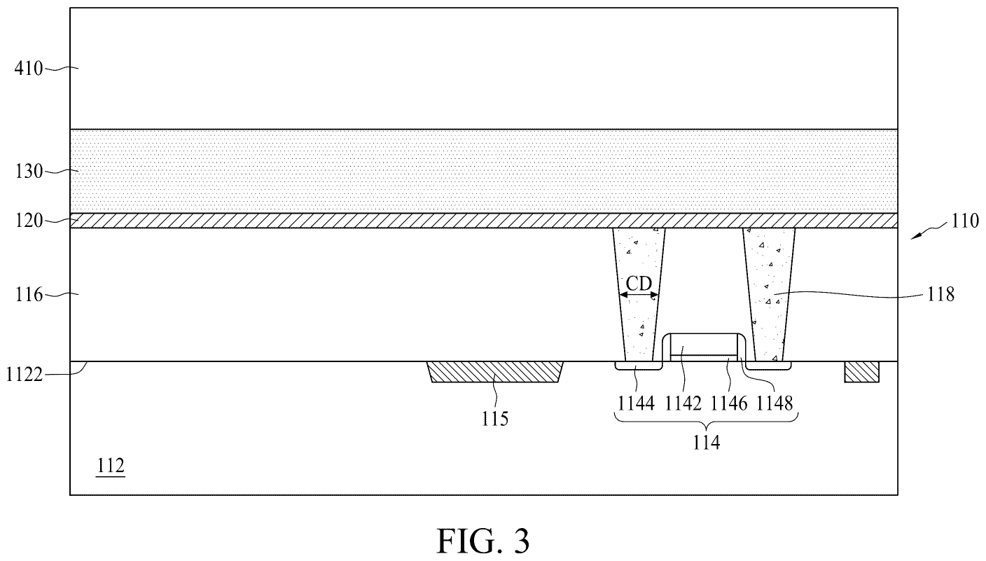

FIG. 2 is a flow diagram illustrating a method 300 of manufacturing a semiconductor device 10 in accordance with some embodiments of the present disclosure. FIGS. 3 to 24 are schematic diagrams illustrating various fabrication stages constructed according to the method 300 for manufacturing the semiconductor device 10 in accordance with some embodiments of the present disclosure. The stages shown in FIGS. 3 to 24 are also illustrated schematically in the flow diagram in FIG. 2. In the subsequent discussion, the fabrication stages shown in FIGS. 3 to 24 are discussed in reference to the process steps shown in FIG. 2.

Referring to FIG. 3, a block layer 120 and a dielectric layer 130 are sequentially stacked on a substrate 110 according to a step S302 in FIG. 2. The substrate 110 includes a semiconductor wafer 112 and one or more main components 114 disposed in or on the semiconductor wafer 112. The semiconductor wafer 112 can be made of silicon. Alternatively or additionally, the semiconductor wafer 112 may include other elementary semiconductor materials such as germanium. In some embodiments, the semiconductor wafer 112 is made of a compound semiconductor such as silicon carbide, gallium arsenic, or indium phosphide.

The main components 114 can include active components, such as transistors and/or diodes, and passive components, such as capacitors, resistors or the like. The main component 114, an access transistor for example, includes a gate electrode 1142 on the semiconductor wafer 112, impurity regions 1144 on either side of the gate electrode 1142, and a gate dielectric 1146 between the semiconductor wafer 112 and the gate electrode 1142. In some embodiments, the gate electrode 1142 may include, but is not limited to, doped polysilicon, or metal-containing material comprising tungsten, titanium, or metal silicide.

The impurity regions 1144, connected to an upper surface 1122 of the semiconductor wafer 112, serve as drain and source regions of the access transistor. The impurity regions 1144 can be formed by introducing dopants into the semiconductor wafer 112. The introduction of the dopants into the semiconductor wafer 112 is achieved by a diffusion process or an ion-implantation process. The dopant introduction may be performed using boron or indium if the respective access transistor is a p-type transistor, or using phosphorous, arsenic, or antimony if the respective access transistor is an n-type transistor.

The gate dielectric 1146, disposed on the upper surface 1122 of the semiconductor wafer 112, is employed to maintain capacitive coupling of the gate electrode 1142 and a conductive channel between the drain and source regions. The gate dielectric 1146 may include oxide, nitride, oxynitride or high-k material. The main component 114 of the access transistor may further include gate spacers 1148 on sidewalls of the gate electrode 1142 and the gate dielectric 1146. The gate spacers 1148 are optionally formed by depositing a spacer material (such as silicon nitride or silicon dioxide) to cover the gate electrode 1142 and the gate dielectric 1146, and performing an anisotropic etching process to remove portions of the spacer material from horizontal surfaces of the gate electrode 1142 and the gate dielectric 1146.

In some embodiments, isolation features 115, such as shallow trench isolation (STI) features or local oxidation of silicon (LOCOS) features, can be introduced in the semiconductor wafer 112 to define and isolate various main components 114 in the semiconductor wafer 112. In other words, the main components 114 are formed in active areas (not shown) defined by the isolation features 115.

The substrate 110 further includes an insulating layer 116 and a plurality of conductive plugs 118 in the insulating layer 116. The insulating layer 116 can be formed by uniformly depositing a dielectric material, using, for example, a chemical vapor deposition (CVD) process, to cover the upper surface 1122 of the semiconductor wafer 112 and the main components 114. Alternatively, the insulating layer 116 may be formed on the semiconductor wafer 112 and the main components 114 using a spin-coating process. In some embodiments, the insulating layer 116 may be planarized, using, for example, a chemical mechanical polishing (CMP) process, to yield an acceptably flat topology. The insulating layer 116 can include oxide, tetraethyl orthosilicate (TEOS), undoped silicate glass (SOG), phosphosilicate glass (PSG), borosilicate glass (BSG), borophosphosilicate glass (BPSG), fluorosilicate glass (FSG), spin-on glass (SOG), tonen silazane (TOSZ), or a combination thereof.

The conductive plugs 118 penetrate through the insulating layer 116 and contact the impurity regions 1144, respectively. The conductive plugs 118, including tungsten, have a critical dimension CD, which may gradually increase at positions of increasing distance from the upper surface 1122 of the semiconductor wafer 112. Generally, the conductive plugs 118 are formed in the insulating layer 116 using a damascene process. The main components 114, the isolation features 115, the insulating layer 116, and the conductive plugs 118 are formed in or on the semiconductor wafer 112 during front-end-of-line processes.

After the formation of the substrate 110, the block layer 120 is deposited on the substrate 110 to conformally cover the insulating layer 116 and the conductive plugs 118. The block layer 120 can be blanketly deposited on the substrate 110 using a CVD process or a physical vapor deposition (PVD) process, for example. In some embodiments, the block layer 120 includes silicon-containing dielectric, such as silicon carbide or silicon nitride.

Subsequently, a dielectric layer 130 is deposited on the block layer 120, in order to protect against contamination and mitigate stress at the interface between the substrate 110 and the dielectric layer 130. The dielectric layer 130 may include silicon oxide, silicon nitride, oxynitride, BSG, low-k material, another suitable material or a combination thereof. The dielectric layer 130 may be formed using vapor deposition processes. After the deposition of the dielectric layer 130, a planarizing process can be performed on the dielectric layer 130 to yield an acceptably flat topology.

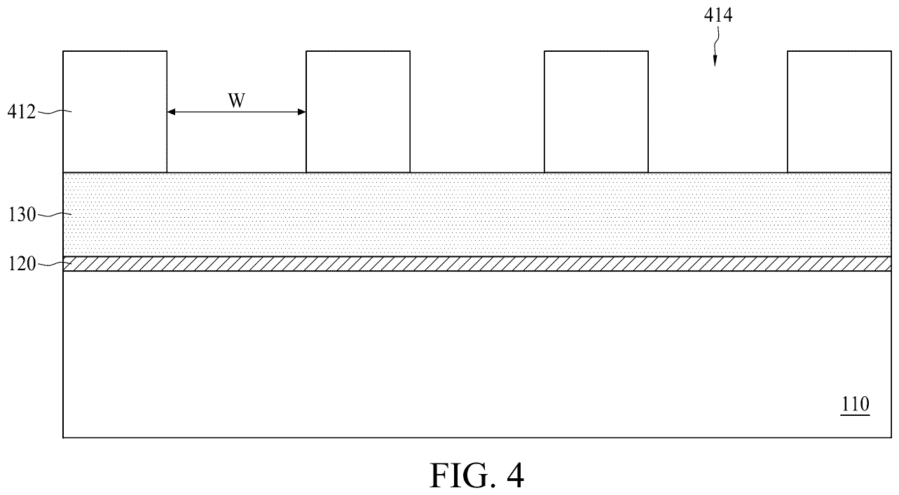

Next, a photoresist layer 410 is applied over the entire dielectric layer 130 by a spin-coating process and then dried using a soft-baking process. The photoresist layer 410, including photosensitive material, is exposed and developed to form a feature pattern 412, shown in FIG. 4, to expose portions of the dielectric layer 130. The feature pattern 412 includes a plurality of windows 414 having a width W, and portions of the dielectric layer 130 to be subsequently etched are exposed through the windows 414.

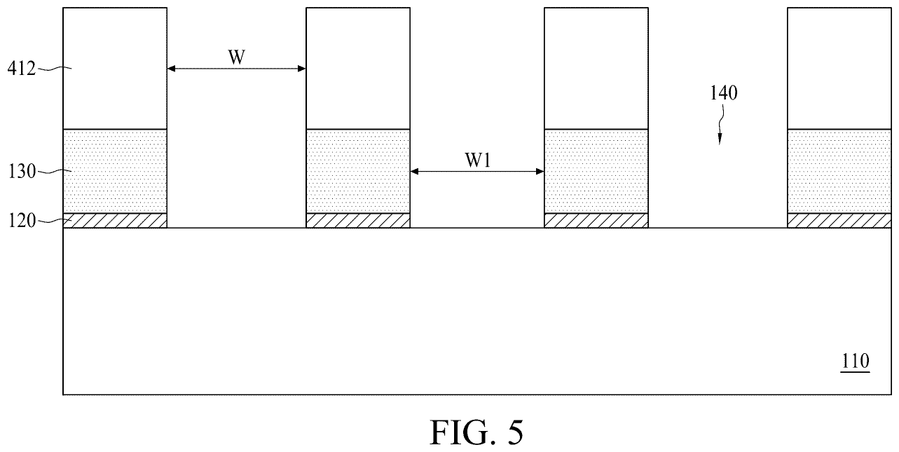

Referring to FIGS. 4 and 5, portions of the dielectric layer 130 and the block layer 120 not covered by the feature pattern 412 are removed to form multiple openings 140 according to a step S304 in FIG. 2. The openings 140 have a first width W1, which is identical to the width W of the window 414 in the feature pattern 412. The openings 140, penetrating through the dielectric layer 130 and the block layer 120, can be formed using an etching process utilizing multiple etchants, selected based on the materials of the block layer 120 and the dielectric layer 130, to sequentially etch the dielectric layer 130 and the block layer 120 until portions of the substrate 110 are exposed. The feature pattern 412 is removed using an ashing process or a strip process, for example, after the openings 140 are created.

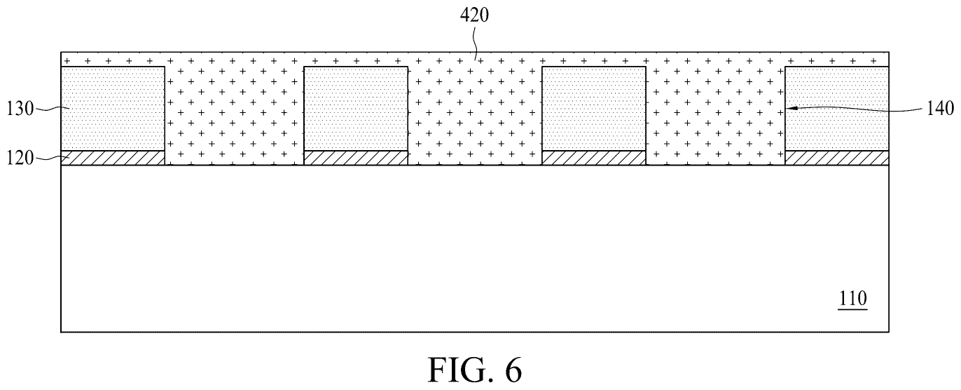

Referring to FIG. 6, a first sacrificial layer 420 is applied to fill the openings 140 according to a step S305. The first sacrificial layer 420, having a sufficient thickness to fill the openings 140, not only fills the openings 140 but also covers the dielectric layer 130. The first sacrificial layer 420, including photosensitive material, is applied over the substrate 110 by a spin-coating process and then dried using a soft-baking process, wherein the soft-baking process can remove solvent from the photosensitive material and harden the photosensitive material.

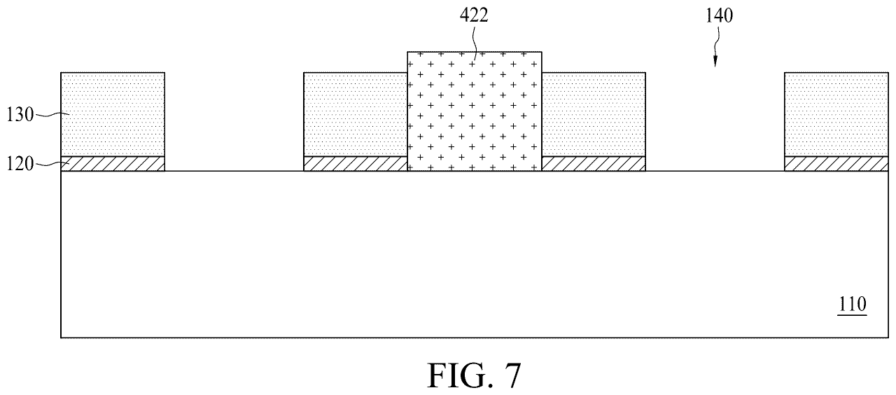

Next, an exposure process is performed, according to a step S306, to expose portions of the first sacrificial layer 420 to actinic radiation through a target mask (not shown), so that a duplicate of a geometric pattern appears in the first sacrificial layer 420. After the exposure process, a developing process is performed to preferentially remove the exposed portions of the first sacrificial layer 420, while unexposed portion(s) 422 of the first sacrificial layer 420 (hereinafter referred to as the “sacrificial block(s) 422”), as shown in FIG. 7, are left in place (step S307 in FIG. 2). As can be seen in FIG. 7, one of the openings 140, penetrating through the dielectric layer 130 and the block layer 120, is occupied by the sacrificial block 422.

A post-baking process can be performed to drive off the solvent from the sacrificial block 422 in the opening 140, and toughens and improves adhesion of the sacrificial block 422 after the developing process. In some embodiments, a deep ultraviolet (UV) treatment (baking the sacrificial block 422 at about 150 to 200 degrees Celsius in UV light) may be used to further strengthen the sacrificial block 422 for better resistance against subsequent processes.

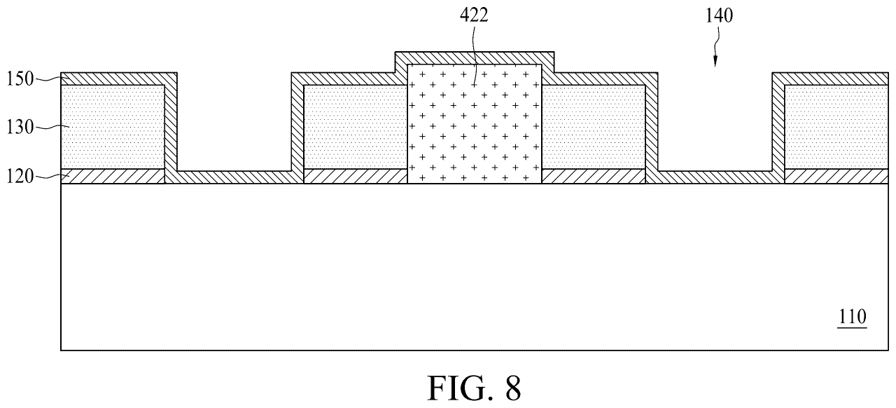

Referring to FIG. 8, an insulative film 150 is conformally disposed on the dielectric layer 130, the sacrificial block 422, and portions of the substrate 110, the block layer 120 and the dielectric layer 130 exposed by the openings 130 not occupied by the sacrificial block 422 (step S308 in FIG. 2). The insulative film 150 has a substantially uniform thickness and a topology following a topology of the sacrificial block 422, portions of the dielectric layer 130 over the block layer 120, and portions of the dielectric layer 130, the block layer 120 and the substrate 110 exposed by the opening 140. That is, the insulative film 150 does not fill the openings 140 not occupied by the sacrificial block 422. By way of example, the insulative film 150 includes oxide or high-k material and can be deposited using a CVD process, an atomic layer deposition (ALD) process, or the like.

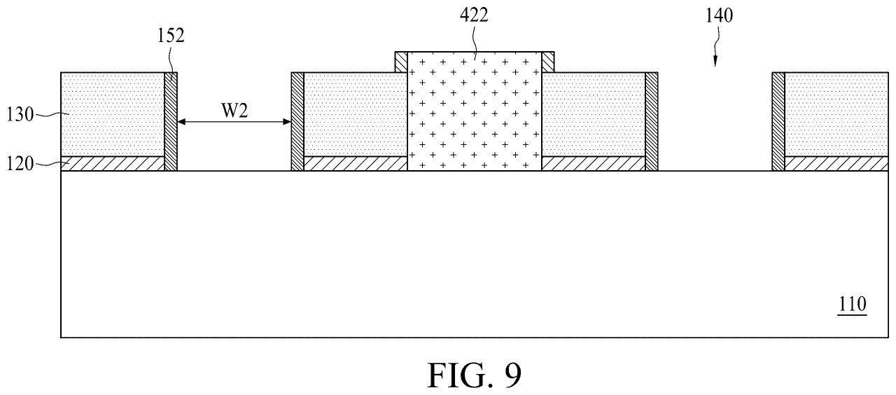

The method 300 then proceeds to the step S309, in which a removal process is performed to remove portions of the insulative film 150 covering the substrate 110, as shown in FIG. 9. Accordingly, one or more insulative liners 152 are formed. Specifically, an anisotropic etching process is performed to remove horizontal potions of the insulative film 150 on the substrate 110, the dielectric layer 130 and the sacrificial block 422, while vertical portions of the insulative film 150 are left on portions of the block layer 120 and the dielectric layer 130 exposed by the openings 140, to thereby form a plurality of insulative liners 152 on sidewalls of the dielectric layer 130 and the block layer 120 exposed by the openings 140. The chemistry of the anisotropic etching process can be selective to the material of the insulative film 150. In other words, no substantial quantities of the material of the substrate 110, the block layer 120, the dielectric layer 130, or the sacrificial block 422 are removed during the etching of the horizontal portions of the insulative film 150. After the removal process, the openings 140, where the insulative liners 152 reside, have a second width W2.

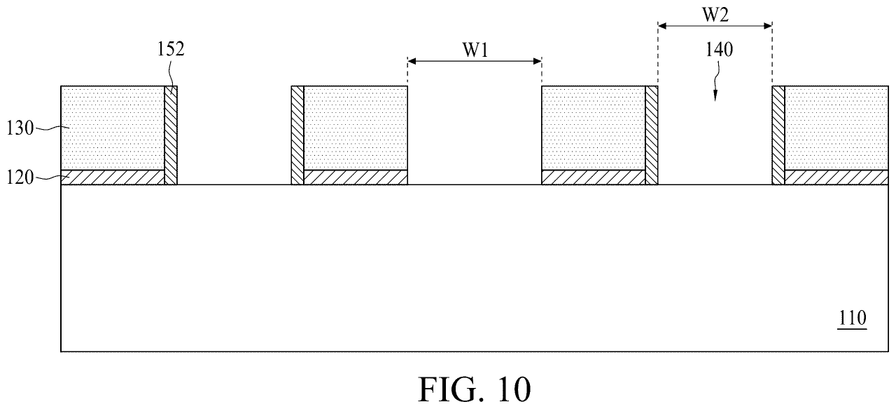

Referring to FIG. 10, after the formation of the insulative liners 152, another removal process is performed to remove the sacrificial block 422 according to a step S310 in FIG. 2. Accordingly, the opening 140, which was occupied by the sacrificial block 422 and has the first width W1, is reopened. The insulative film 150 was not deposited in the opening 140, which was entirely occupied by the sacrificial block 422, and thus the first width WI of the opening 140, which was occupied by the sacrificial block 422, is greater than the second width W2 of the openings 140, where the insulative liners 152 reside. In some embodiments, an ashing process or a wet strip process may be used to remove the sacrificial block 422, wherein the wet strip process may chemically alter the sacrificial block 422 so that it no longer adheres to the block layer 120 and dielectric layer 130.

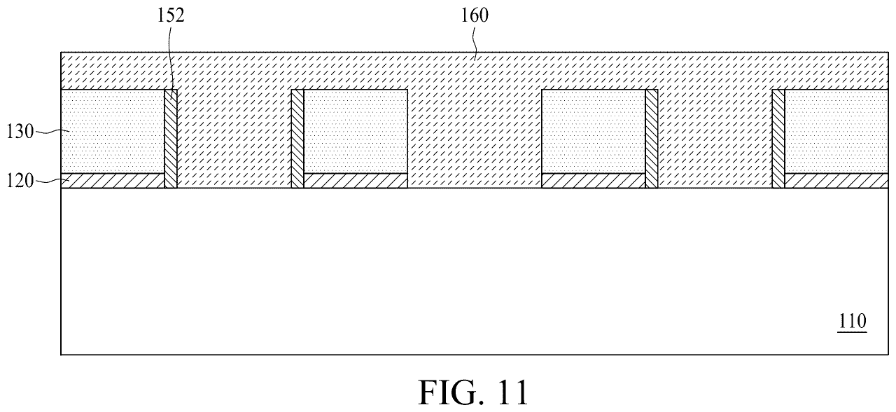

Referring to FIG. 11, a conductive material 160 is deposited in the openings 140 having the first and second widths W1 and W2 (as shown in FIG. 10). In some embodiments, the conductive material 160 not only fills up the openings 140 but also covers the dielectric layer 130 and the insulative liners 152 to facilitate the deposition of the conductive material 160. More particularly, the conductive material 160 is uniformly deposited on the substrate 110, the dielectric layer 130 and the insulative liners 152 until the openings 140 are entirely filled. The conductive material 160 is made of conductive material, such as copper, copper alloy, aluminum, aluminum alloy or a combination thereof. The conductive material 160 is formed on the substrate 110, the dielectric layer 130 and the insulative liners 152 using a plating process or a CVD process.

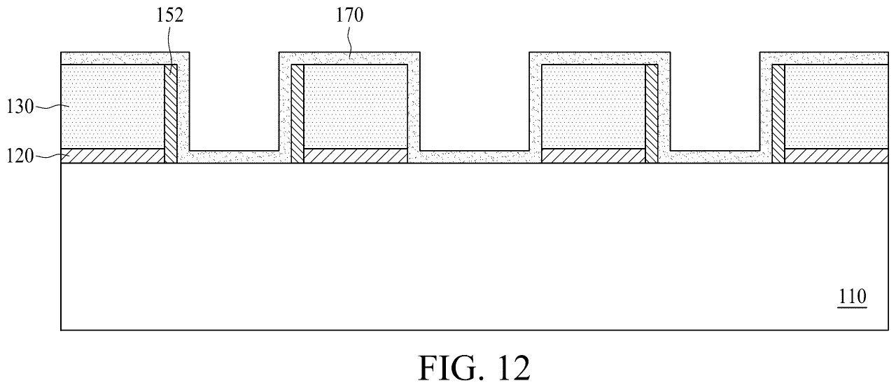

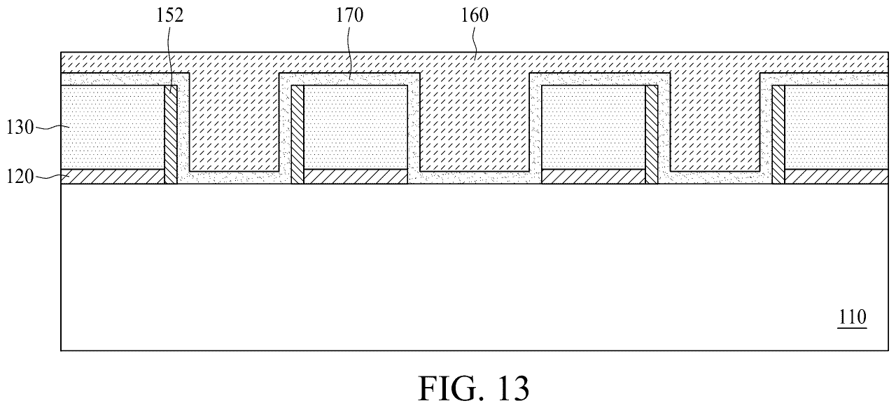

Referring to FIG. 12, if the conductive material is a copper-containing material, which is easy to diffuse, a diffusion barrier layer 170 may be formed, for example, using a PVD process, a CVD process, or the like in the openings 140 prior to the deposition of the conductive material 160 (step S311 in FIG. 2). The diffusion barrier layer 170 is conformally deposited on the dielectric layer 130, the insulative liner 152, and portions of the substrate 110 exposed to the openings 140. The diffusion barrier layer 170 may be a single-layered structure including refractory materials (such as tantalum or titanium), refractory metal nitride, or refractory meal silicon nitrides. In alternative embodiments, the diffusion barrier layer 170 may comprise a multi-layered structure including one or more refractory metals, refractory metal nitrides, or refractory metal silicon nitrides. Next, the conductive material 160 is deposited to completely fill the openings 140 coated with the diffusion barrier layer 170, as shown in FIG. 13.

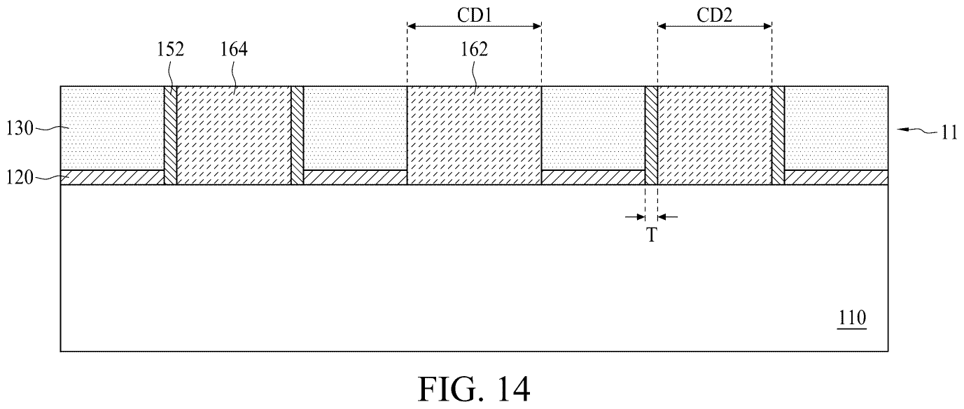

Referring to FIG. 14, after the deposition of the conductive material 160, a polishing process is performed to remove the conductive material 160 above the openings 140 and thus form one or more first conductive blocks 162, surrounded by the block layer 120 and the dielectric layer 130, and one or more second conductive blocks 164, surrounded by the insulative liner 152, according to a step S312 in FIG. 2. After the removal of the superfluous conductive material 160, the dielectric layer 130 and the insulative liner 152 are exposed. Consequently, an interconnection structure 10 including the dielectric layer 130, the insulative liner 152 and the first and second conductive blocks 162 and 164 is formed.

As shown in FIG. 14, the first conductive block 162 has a first critical dimension CD1, and the second conductive blocks 164 have a second critical dimension CD2 less than the first critical dimension CD1. Generally, for a given material, a resistance of an object is inversely proportional to its cross-sectional area; therefore, for the first conductive block 162 and the second conductive block 164 made of a same material and having a same length (or height), the first conductive block 162 can have less resistance than the second conductive block 164.

In some embodiments, the insulative liner 152 has a thickness T, and a sum of the second critical dimension CD2 and two times the thickness T is equal to the first critical dimension CD1. That is, the second critical dimension of the second conductive block 164 can be adjusted by precisely controlling a thickness of the insulative film 150 conformally deposited on the sidewalls of the block layer 120 and the dielectric layer 130 exposed through the openings 140 because the insulative liner 152 and the second conductive block 164 are collectively disposed in the same opening 140, and thus it may be observed that an effective resistance of the first and second conductive blocks 162 and 164 can be controlled by adjusting the thickness of the insulative film 150.

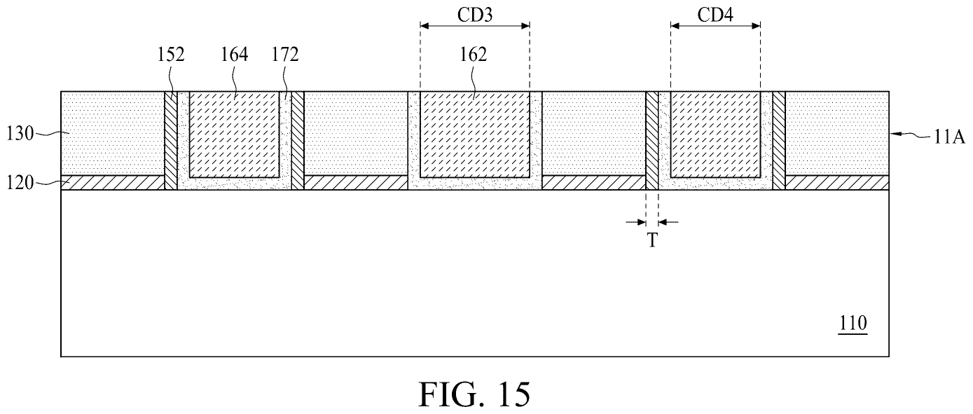

In embodiments where the conductive material 160 is deposited on the diffusion barrier layer 170 (shown in FIG. 13), the polishing process is performed to remove the conductive material 160 and the diffusion barrier layer 170 from the dielectric layer 130, as shown in FIG. 15 (step S313 in FIG. 2). Consequently, one or more first conductive blocks 162, surrounded by the diffusion barrier liners 172 and contacting the block layer 120 and the dielectric layer 130, and one or more second conductive blocks 164, surrounded by the diffusion barrier liners 172 and contacting the insulative liners 152, are formed, and thus an interconnection structure 11A is formed. The first conductive block 162 has a third critical dimension CD3, and the second conductive blocks 164 have a fourth critical dimension CD4 less than the third critical dimension CD3.

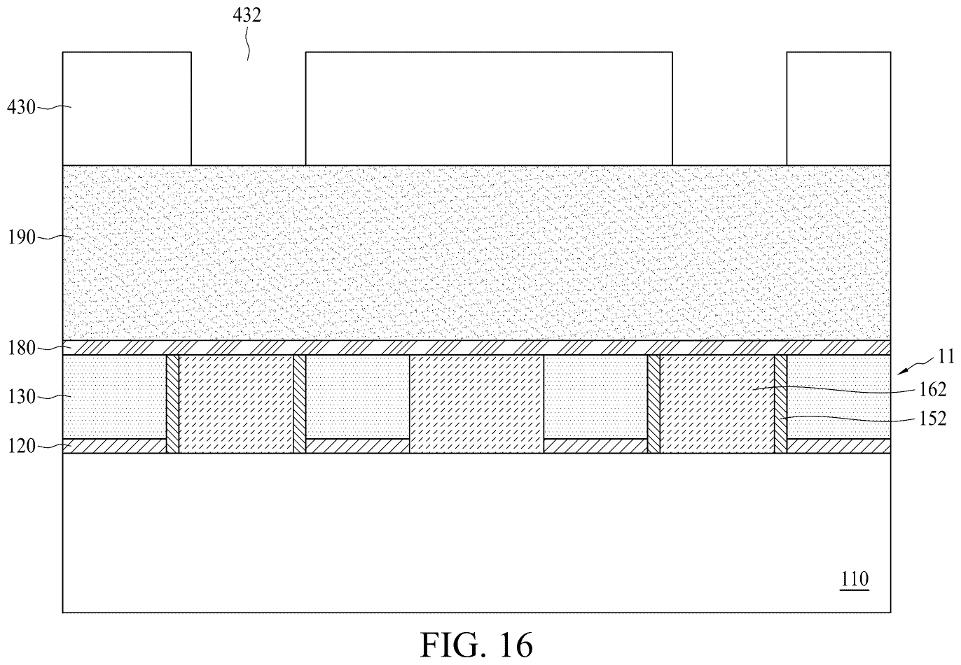

Referring to FIG. 16, after the formation of the first and second conductive blocks 162 and 164, a first metallic layer 180 and an inter-layer dielectric (ILD) layer 190 are sequentially disposed to cover the dielectric layer 130, the insulative liners 152, and the first and second conductive blocks 162 and 164 according to a step S314 in FIG. 2. The first metallic layer 180 can be made of conductive material that is heat resistant. In some embodiments, the first metallic material 180 is made of material including tungsten, copper, aluminum, gold, titanium or a combination thereof, and is formed using a plating process or a CVD process. The method of forming the ILD layer 190 can include a CVD process, a spin-coating process, or another suitable process that can form dielectric material.

Next, a pattern mask 430, including multiple windows 432, is formed on the ILD layer 190. The pattern mask 430 is formed by steps including (1) conformally coating a photosensitive material on the ILD layer 190, (2) exposing portions of the photosensitive material to radiation (not shown), and (3) developing the photosensitive material, thereby forming the windows 432 defining the pattern to etch through the ILD layer 190.

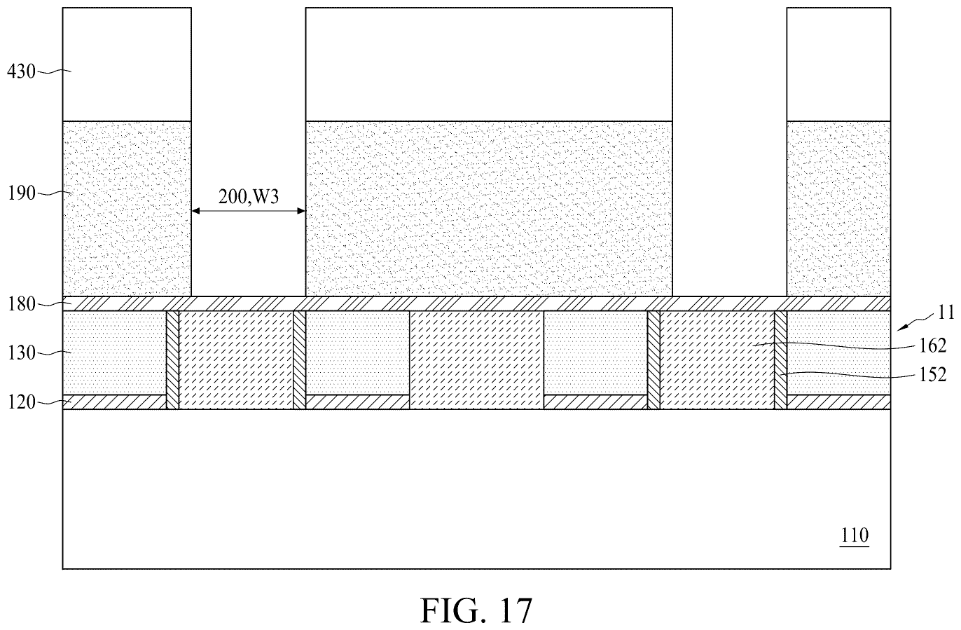

Referring to FIG. 17, an etching process is performed to remove portions of the ILD layer 190 not protected by the pattern mask 430 according to a step S315 in FIG. 2. Consequently, a plurality of trenches 200 are formed, and portions of the first metallic layer 180 are exposed. In other words, the trenches 200, having a uniform third width W3, penetrate through the ILD layer 190.

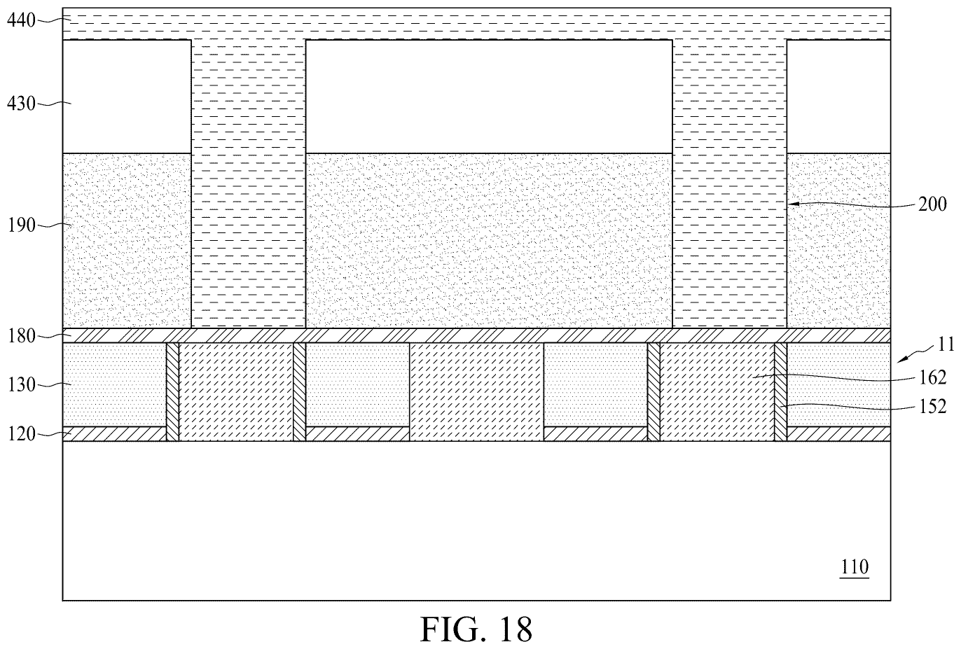

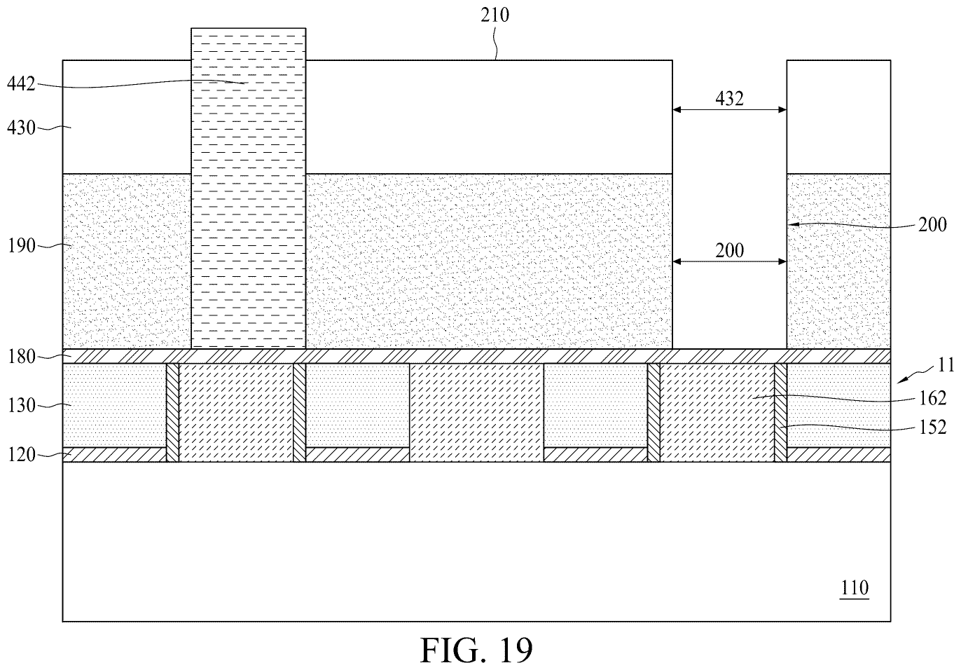

Referring to FIG. 18, a second sacrificial layer 440 is applied to fill the trenches 200. The second sacrificial layer 440 not only fills the trenches 200 and the windows 432 but also covers the pattern mask 430. Next, the method proceeds to a step S316 shown in FIG. 2, in which a lithography process is performed to form a sacrificial plug 442, as shown in FIG. 19. The lithography process typically involves exposure to ultraviolet and/or deep ultraviolet light, followed by subsequent baking, including a photochemical reaction which changes the solubility of the exposed regions of a photoresist material. Thereafter, an appropriate developer, typically an aqueous base solution, is used to selectively remove the photoresist material in the exposed regions (for positive-tone resist).

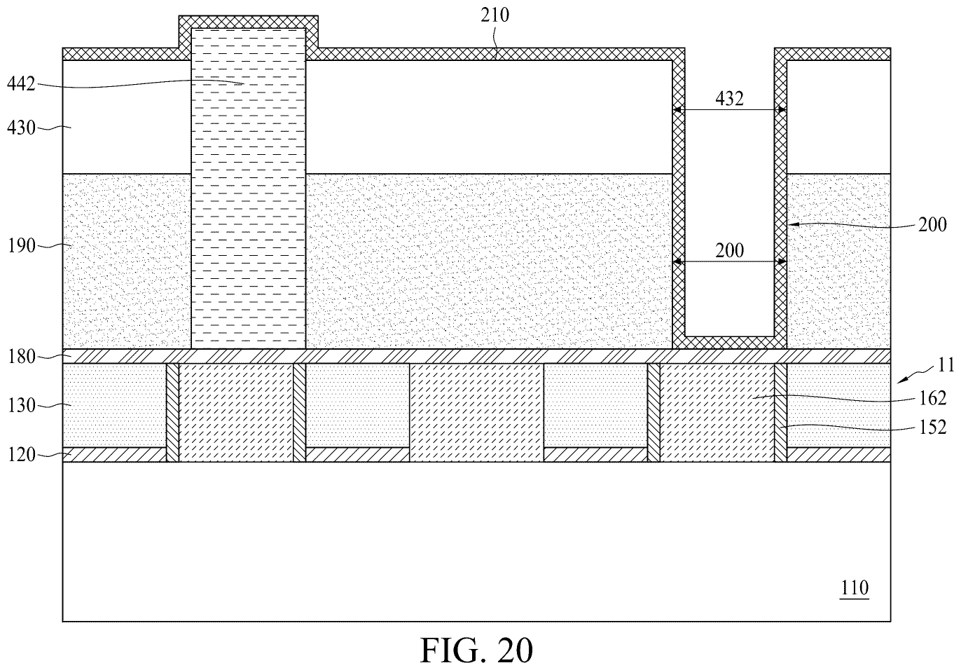

Referring to FIG. 20, an isolation film 210 is conformally formed on the sacrificial plug 442, the pattern mask 430, and in the windows 432 and the trenches 200 to cover the first metallic layer 180, the ILD layer 190, the pattern mask 430 and the sacrificial plug 442 according to a step S317. As shown in FIG. 20, the isolation film 210 may include horizontal portions capping the portions of sacrificial plug 442, the pattern mask 430 and the first metallic layer 180, and vertical portions coated on portions of the sacrificial plug 442, portions of the pattern mask 430 exposed by the window 432, and portions of the ILD layer 190 exposed by the trench 200.

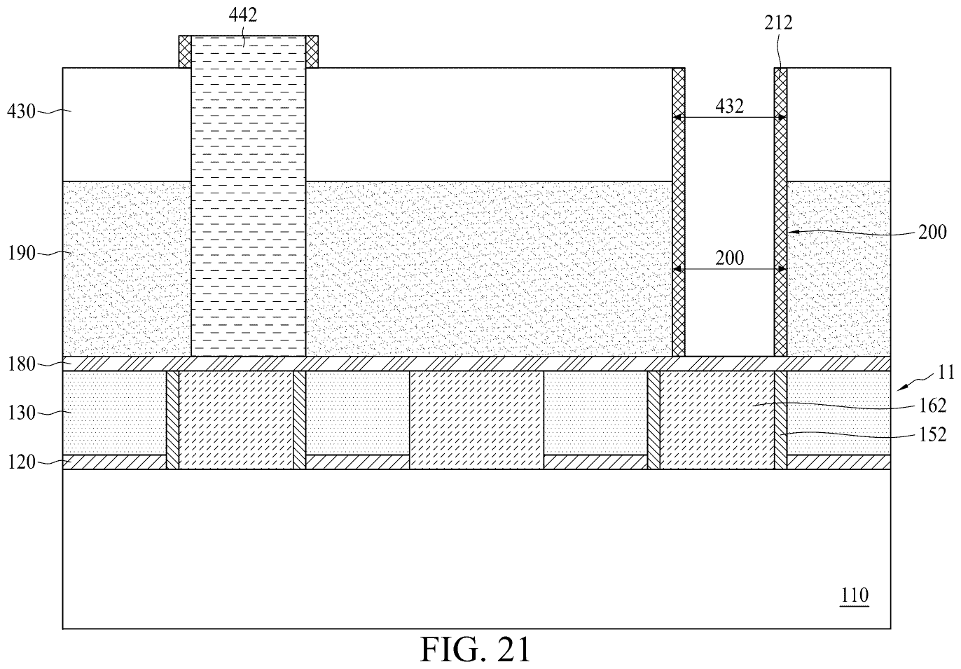

Subsequently, an etching process is conducted to at least remove portions of the isolation film 210 in contact with the first metallic layer 180, as shown in FIG. 21. In some embodiments, the isolation film 210 can be anisotropically etched. Accordingly, the horizontal portions of the isolation film 210 are removed, while the vertical portions of the isolation film 210 are left on sidewalls of the ILD layer 190 exposed by the trench 200 and the pattern mask 430 exposed by the window 432 to form the isolation liner 212 (step S318 in FIG. 2).

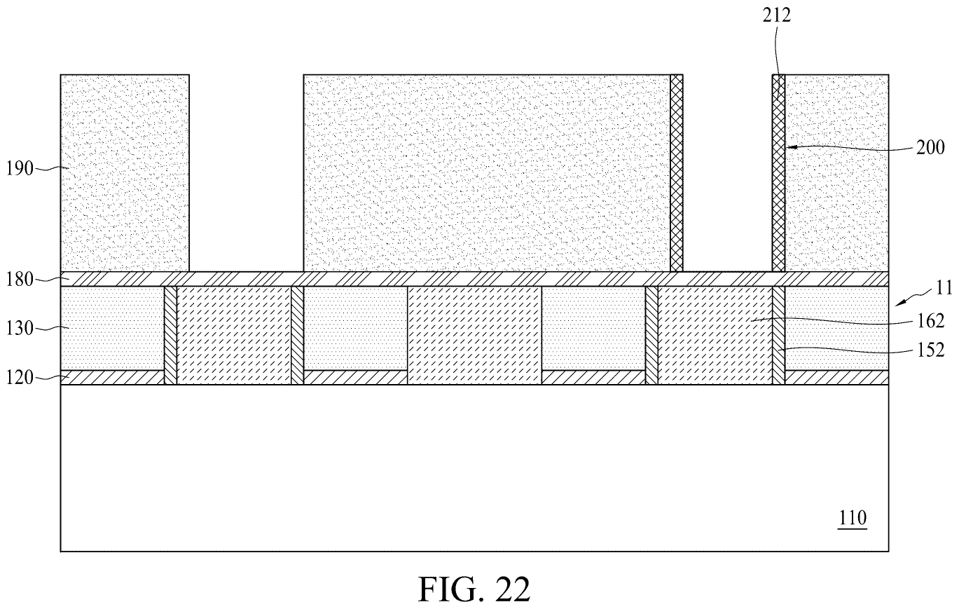

After the isolation liners 212 are formed, the pattern mask 430 and the sacrificial plug 442 are removed, as shown in FIG. 22, using an ashing process or a strip process, for example, according to the step S320 in FIG. 2.

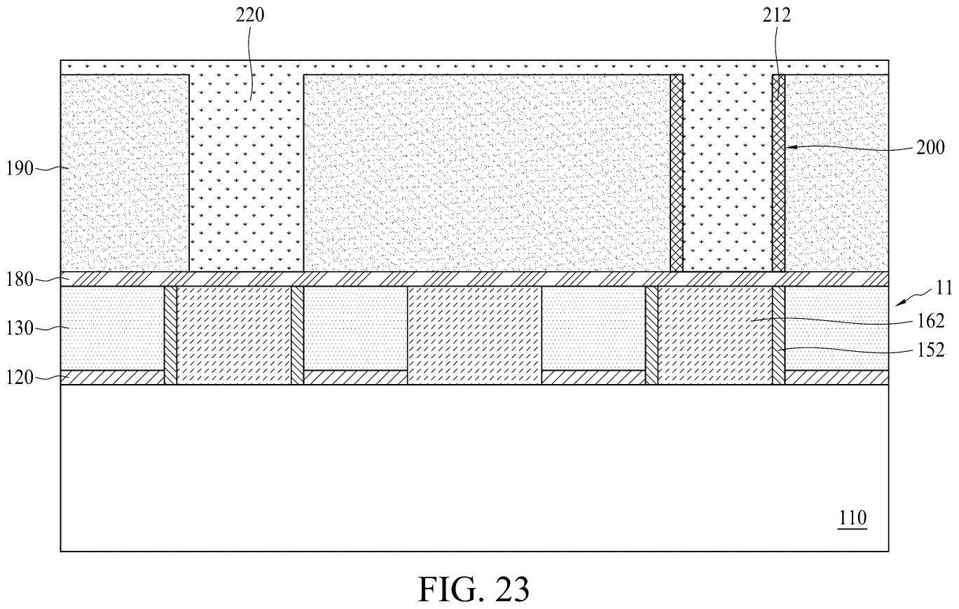

The method 300 then proceeds to the step S322, in which a plating process is performed to fill the trench 200 with conductive material 220, as shown in FIG. 23. The conductive material 220 can be conformally and uniformly deposited, by way of an electroplating process, for example, on the ILD layer 190 and the isolation liners 212 until the trenches 200 are completely filled. The conductive material 220 can include copper, aluminum, or the like.

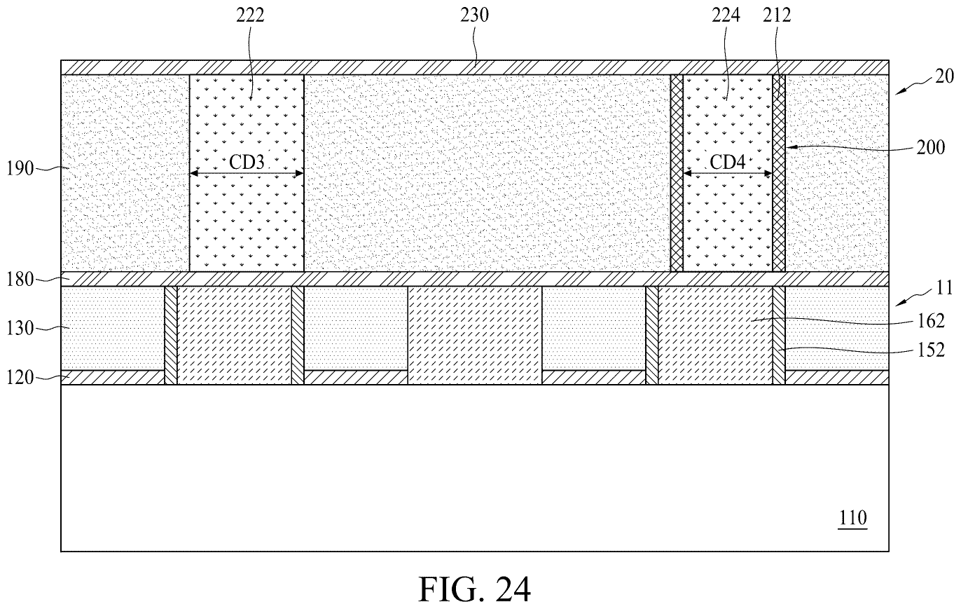

Next, at least one removal process is then performed to remove the conductive material 220 above the trenches 200, thereby exposing the ILD layer 190 (as shown in FIG. 24). Consequently, at least one first conductive feature 222, surrounded by the ILD layer 190, and at least one second conductive feature 224, surrounded by the isolation liner 212, are formed. The first conductive feature 222 has a third critical dimension CD3, and second conductive feature 224 has a fourth critical dimension CD4 less than the third critical dimension CD3. As mentioned above, resistances of the first and second conductive features 222 and 224 made of a same material and have a same length (height) are inversely proportional to their cross-sectional areas; therefore, the first conductive feature 222 can have less resistance than the second conductive features 224. The second conductive features 224 having a smaller critical dimension can be disposed in an area in which a higher resistance is required to lower a complexity of circuit design.

Next, the method 300 proceeds to a step S324, in which a second metallic layer 230 is formed to cover the ILD layer 190, the isolation liner 212 and the first and second conductive features 222 and 224. The second metallic layer 230 can be made of conductive material including tungsten, copper, aluminum, gold, titanium or a combination thereof. In some embodiments, the first and second metallic layers 180 and 230 are made of a same conductive material that is heat resistant.

In conclusion, with the configuration of the interconnection structure 11, including the first and second conductive blocks 162 and 164 having different critical dimensions, and the wiring structure 12, including the first and second conductive features 222 and 224 having different critical dimensions, an effective resistance of the semiconductor device 10 can be effectively controlled.

One aspect of the present disclosure provides a wiring structure. The wiring structure comprises a semiconductor element, a metallic layer above the semiconductor element, at least one first conductive feature between the semiconductor element and the metallic layer, at least one second conductive feature between the semiconductor element and the metallic layer, and at least one insulative liner enclosing the second conductive feature. The first conductive feature has first critical dimension, and the second conductive feature has a second critical dimension less than the first critical dimension.

One aspect of the present disclosure provides a semiconductor device. The semiconductor device comprises a substrate, a wiring structure disposed over the substrate, and an interconnection structure sandwiched between the substrate and the wiring structure. The wiring structure comprises a first metallic layer, a second metallic layer above the first metallic layer, at least one first conductive feature and at least one second conductive feature disposed between the first and second metallic layers, and at least one insulative liner enclosing the second conductive feature. The first conductive feature has a first critical dimension, and the second conductive feature has a second critical dimension less than the first critical dimension.

One aspect of the present disclosure provides a method of manufacturing a semiconductor device. The method comprises steps of depositing a dielectric layer on a substrate, creating a plurality of openings penetrating through the dielectric layer, forming at least one insulative liner in at least one of the openings, and depositing a first conductive material in the openings to form at least one first conductive block physically connected to the dielectric layer and at least one second conductive block surrounded by the insulative liner.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, compositions of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A method of manufacturing a semiconductor device, comprising:
depositing a dielectric layer on a substrate;
creating a plurality of openings penetrating through the dielectric layer;
forming at least one insulative liner in at least one of the openings; and
depositing a first conductive material in the openings to form at least one first conductive block physically connected to the dielectric layer and at least one second conductive block surrounded by the insulative liner.

2. The method of claim 1, wherein the formation of the insulative liner comprises:
forming at least one sacrificial block in at least one of the openings;
depositing an insulative film on the sacrificial block and the dielectric layer and in the openings; and
removing horizontal portions of the insulative film covering the sacrificial block and the substrate;
wherein the formation of the first sacrificial block comprises:
depositing a first sacrificial layer on the dielectric layer and in the opening;
performing an exposure process to expose portions of the first sacrificial layer; and
performing a developing process to remove the exposed portions of the first sacrificial layer,
wherein after the formation of the insulative liner, the sacrificial block is removed using an ashing process or a strip process.

3. The method of claim 1, further comprising:
depositing a diffusion barrier layer in the openings prior to the deposition of the first conductive material; and
removing portions of the diffusion barrier layer above the openings after the deposition of the first conductive material.

4. The method of claim 1, further comprising forming a wiring structure on the dielectric layer, the insulative liner, and the first and second conductive features;
wherein the formation of the wiring structure comprises:
depositing a first metallic layer to cover the dielectric layer, the insulative liner, the first conductive block and the second conductive block;
depositing an inter-layer dielectric (ILD) layer on the first metallic layer;
creating a plurality of trenches penetrating through the ILD layer;
forming at least one isolation liner in at least one of the trenches;
depositing a second conductive material in the openings to form at least one first conductive feature surrounded by the ILD layer and at least one second conductive feature surrounded by the isolation liner; and
depositing a second metallic layer to cover the ILD layer, the first conductive feature and the second conductive feature;
wherein the formation of the isolation liner comprises:
forming at least one sacrificial plug in at least one of the trenches;
depositing an isolation film on the sacrificial plug and the ILD layer and in the trenches; and
removing horizontal portions of the isolation film covering the sacrificial plug and the first metallic layer;
wherein the first metallic layer and the second metallic layer are made of a same material.
